(19) United States
(12) Patent Application Publication
(10) Pub. No.: US 2026/0127336 A1
(43) Pub. Date: May 7, 2026

(54) SIMULATION OF CROP PARAMETERS USING WEIGHTED POINT VECTOR LAYERS

(71) Applicant: Laconik Pty Ltd, Canning Vale (AU)

(72) Inventor: Darren HUGHES, Canning Vale (AU)

(21) Appl. No.: 19/379,865

(22) Filed: Nov. 5, 2025

(30) Foreign Application Priority Data
Nov. 6, 2024 (AU) 2024903621

(51) Int. Cl. G06F 30/20

(52) U.S. Cl. CPC G06F 30/20

(57) ABSTRACT

A computer-implemented method for predicting a crop parameter response to an agricultural product across land is provided. The method comprises generating a predictive model that incorporates fixed effects (agricultural product quantities) and random effects (environmental conditions) measured at sampled points on the land. The method further comprises calculating predicted values for the crop parameter at the sampled points using the model, and then generating a point vector layer comprising the predicted values, wherein spatial coordinates corresponding to the sampled points are assigned to the predicted values. An inverse distance weighted interpolation algorithm is then executed to calculate further predicted values for the crop parameter at unsampled points on the land, wherein spatial coordinates for the unsampled points are assigned. The algorithm uses the point vector layer such that a weighted influence of each sampled prediction on each unsampled prediction diminishes as the spatial distance between the relevant spatial coordinates increases.

### FIELD

The present invention relates to agronomy and, more particularly, to a computer-implemented method and system for performing high-resolution crop response simulations for agricultural products.

### BACKGROUND

A variety of different agricultural products are commonly applied onto farmland to improve crop growth and soil conditions and to inhibit pests, weeds and other undesirable conditions. Example products include fertiliser, herbicide, fungicide, insecticide, seed, traits and agricultural biologicals. A manufacturer of a new agricultural product will trial the product before it is commercially released.

Once a grower has decided to purchase a particular agricultural product, the product must be carefully applied onto farmland. This is particularly the case for fertilisers which commonly contain nitrogen. Applying too much or too little nitrogen can inhibit crop growth. Paddocks are typically managed as homogenous units and receive a single excess dose of nitrogen fertiliser that is applied uniformly over the paddock. Over applying nitrogen in this manner is a costly practice and can have significant detrimental effects on the crops, farmland and wider environment. For example, too much nitrogen can cause weed problems, delay crop maturity and increase a crop's susceptibility to diseases, particularly in wheat crops. Too much nitrogen can also lead to excessive late growth which can make crops with weaker stems more susceptible to lodging. Lodging is where crop stems bend at their lower ends which makes the crops difficult to harvest and reduces their yield. Excess nitrogen can also lead to nitrogen losses and environmental damage through ammonia volatilisation, denitrification, runoff and leaching. A variety of factors affect how crops respond to nitrogen. It is difficult to predict how much nitrogen must be applied to an area of farmland to achieve a particular crop yield, or improve the yield by a given amount. Nitrogen doses are, therefore, generally over prescribed in an effort to avoid yield losses or to achieve a target yield or yield increase which leads to the problems described above.

U.S. Pat. No. 10,628,895 B2 filed on 14 Dec. 2015 discloses a computer-implemented method for generating digital models of relative crop yields based on nitrate values on land. The data that is generated by this method enables crop growers to make improved fertiliser decisions to some extent. However, the method does not enable growers to simulate crop responses to agricultural products at a high resolution for an area of land. In turn, the method does not allow growers to make precision fertiliser decisions for an area of farmland.

The preceding discussion of the background art is intended to facilitate an understanding of the present invention only. The discussion is not an acknowledgement or admission that any of the material referred to is or was part of the common general knowledge as at the priority date of the present application.

### SUMMARY

According to the present invention, there is provided a method comprising:
generating, by a computer system, a predictive model for a crop parameter, wherein the predictive model is based on fixed effects representing quantities of an agricultural product and random effects representing environmental conditions measured at sampled points on an area of land;
receiving, at the computer system, data comprising quantities of the agricultural product to be applied to the sampled points and environmental conditions at the sampled points;
generating, by the computer system, a set of first predicted values for the crop parameter at the sampled points using the predictive model and the data received;
generating, by the computer system, a point vector layer that comprises the set of first predicted values, wherein a set of first spatial coordinates that correspond to the sampled points are respectively assigned to the first predicted values in the point vector layer; and
executing, by the computer system, an inverse distance weighted interpolation algorithm, based on the point vector layer, to calculate a set of second predicted values for the crop parameter for unsampled points on the area of land, wherein the interpolation algorithm includes assigning a set of second spatial coordinates that correspond to the unsampled points to the second predicted values respectively, and wherein a weighted influence of each first predicted value on each second predicted value diminishes as the spatial distance between the respective spatial coordinates increases,
such that the first and second sets of predicted values provide a quantitative indication of how the crop parameter is expected to be affected by the agricultural product across the area of land.

The interpolation algorithm may include a normalisation method which provides that the weighted influence of each individual first predicted value that is used to calculate each individual second predicted value is unbiased.

The normalisation method may comprise:
calculating a weight for each individual first predicted value, wherein the weight is inversely proportional to the spatial distance between the respective spatial coordinates that are assigned to the individual first predicted value and the individual second predicted value, to obtain a set of weights;
multiplying each individual first predicted value by each of the weights respectively to obtain a set of scaled first predicted values; and
dividing a sum of the scaled first predicted values by a sum of the weights to obtain the individual second predicted value.

Each weight may be inversely proportional to a fixed power of the spatial distance, wherein the fixed power is greater than one. In one embodiment, the fixed power is equal to two.

The spatial distance may be a euclidean distance between the respective spatial coordinates.

The method may further comprise generating and displaying a map on a display device connected to the computer system, wherein the map graphically depicts a spatial variability of the first and second sets of predicted values across the area of land.

The area of land may be displayed on the map by a set of pixels of the display device, and the method may further comprise calculating and depicting a predicted value of the crop parameter for each of the pixels, such that the pixels display a gradient map depicting the spatial variability in a continuous visual manner.

The crop parameter may relate to a grain or cereal crop, such as wheat, canola, rice, corn, barley, oats, rye or sorghum. In other examples, the crop may be a legume, such as beans, peas, lentils or soybeans. In other examples, the crop may be a fiber crop, such as cotton, flax, hemp or jute. The crop parameter relates to any measurable physical characteristic or condition of the crop. For example, the crop parameter may comprise yield level, protein content, leaf chlorophyll content, oil content, starch content, fibre content, vitamin content, plant height, leaf area or root depth of the crop. The crop parameter may comprise nutrient or mineral content, such as nitrogen (N), phosphorus (P), or potassium (K) content, obtained by leaf tissue testing. The agricultural product may comprise N or other substances such as herbicide, fungicide, insecticide, seed, traits or an agricultural biological.

The environmental conditions include any physical characteristic or variable relating to the crop's environment that influences the crop's growth, health and/or yield potential. In embodiments, the environmental conditions may relate to the soil in which the crop is to be grown. For example, the environmental conditions may comprise soil water/moisture level, texture, rock quantity, pH, salinity level or mineral and/or nutrient content, including essential plant nutrients such as N, P, K, sulphur(S) or carbon (C) content. In other embodiments, the environmental conditions may relate to climatic conditions of the area of land, such as average air temperature, solar radiation levels, average wind speed and/or average air humidity levels. The environmental conditions may relate to frequency and rates/volumes of water received on the area of land, including by precipitation and irrigation water. In other examples, the environmental conditions may include pest incidence levels for the area of land. The temporal and/or spatial variability of the relevant environmental conditions may be taken into account in the random effects.

The method may further comprise:
calculating, by the computer system, a further set of quantities of the agricultural product, wherein the further set of quantities correspond to the unsampled points respectively and are for growing the crop in accordance with the second predicted values; and
remotely transmitting at least the further set of quantities from the computer system to a control system of an agricultural vehicle to enable the control system to cause the agricultural vehicle to apply the agricultural product to the area of land autonomously in accordance with the further set of quantities.

The further set of quantities may be calculated by interpolating the quantities of the agricultural product that are to be applied at the sampled points. In other examples, the method may comprise:
executing, by the computer system, an interpolation algorithm to generate environmental data containing estimates of the environmental conditions of the area of land at the unsampled points, wherein the interpolation algorithm generates the environmental data based on the environmental conditions of the area of land at the sampled points; and
generating, by the computer system, the further set of quantities using a model inversion of the predictive model, wherein the model inversion receives the environmental data and the set of second predicted values as inputs.

The present invention also provides a system comprising a processor, wherein the processor is configured to:
generate a predictive model for a crop parameter, wherein the predictive model is based on fixed effects representing quantities of an agricultural product and random effects representing environmental conditions measured at sampled points on an area of land;
receive data comprising quantities of the agricultural product to be applied to the sampled points and environmental conditions at the sampled points;
generate a set of first predicted values for the crop parameter at the sampled points using the predictive model and the data received;
generate a point vector layer that comprises the set of first predicted values, wherein a set of first spatial coordinates that correspond to the sampled points are respectively assigned to the first predicted values in the point vector layer; and
execute an inverse distance weighted interpolation algorithm, based on the point vector layer, to calculate a set of second predicted values for the crop parameter for unsampled points on the area of land, wherein the interpolation algorithm includes assigning a set of second spatial coordinates that correspond to the unsampled points to the second predicted values respectively, and wherein a weighted influence of each first predicted value on each second predicted value diminishes as the spatial distance between the respective spatial coordinates increases, such that the first and second sets of predicted values provide a quantitative indication of how the crop parameter is expected to be affected by the agricultural product across the area of land.

The present invention also provides a computer-readable non-transitory medium storing executable instructions which, when executed by a computer system, cause the computer system to:
generate a predictive model for a crop parameter, wherein the predictive model is based on fixed effects representing quantities of an agricultural product and random effects representing environmental conditions measured at sampled points on an area of land;
receive data comprising quantities of the agricultural product to be applied to the sampled points and environmental conditions at the sampled points;
generate a set of first predicted values for the crop parameter at the sampled points using the predictive model and the data received;
generate a point vector layer that comprises the set of first predicted values, wherein a set of first spatial coordinates that correspond to the sampled points are respectively assigned to the first predicted values in the point vector layer; and
execute an inverse distance weighted interpolation algorithm, based on the point vector layer, to calculate a set of second predicted values for the crop parameter for unsampled points on the area of land, wherein the interpolation algorithm includes assigning a set of second spatial coordinates that correspond to the unsampled points to the second predicted values respectively, and wherein a weighted influence of each first predicted value on each second predicted value diminishes as the spatial distance between the respective spatial coordinates increases,
such that the first and second sets of predicted values provide a quantitative indication of how the crop parameter is expected to be affected by the agricultural product across the area of land.

### BRIEF DESCRIPTION OF DRAWINGS

Embodiments of the invention will now be described by way of example only with reference to the accompanying drawings, in which:

FIG. 1 is a schematic view of a computer and an area of land, wherein the computer is configured to execute a method for calculating a set of predicted values for a crop parameter for a crop to be grown on the area of land according to an example embodiment of the invention;

FIG. 2 is a schematic view of a point vector layer generated on the computer by the method;

FIG. 3 is a flow diagram of a mixed-effects predictive model used in the method;

FIG. 4 is a schematic plan view of the area of land that depicts a plurality of sampled points on the area of land;

FIG. 5 is a flow diagram of an inverse distance weighted interpolation algorithm used in the method;

FIG. 6 is a schematic plan view of the area of land, wherein the point vectors in the point vector layer are depicted relative to a plurality of unsampled points on the area of land;

FIG. 7 shows a gradient map that corresponds to the area of land, wherein the gradient map is rendered on a visual display connected to the computer in the method;

FIG. 8 is schematic diagram of a system for generating the mixed-effects predictive model used in the method;

FIG. 9 is an annotated plan view of the area of land, wherein the area of land is used in a crop trial that is carried out to generate the mixed-effects predictive model;

FIG. 10 is a flow diagram of functionality executed by the system of FIG. 8; and

FIG. 11 is an annotated aerial view of a pair of test regions of the area of land that are used in the crop trial.

### DESCRIPTION OF EMBODIMENTS

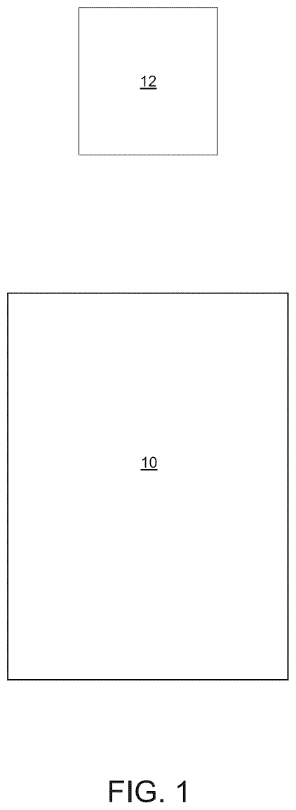

Referring to FIG. 1, an example embodiment of the present invention provides a method for calculating a set of predicted values for a crop parameter, wherein the crop parameter relates to a crop to be grown on an area of agricultural land 10. The area of land 10 typically comprises a paddock or a similar defined area of agricultural farmland. The crop may be of any type including grains/cereals—such as wheat, canola, rice, corn, barley, oats, rye or sorghum—and legumes, such as beans, peas, lentils or soybeans—and fiber crops, such as cotton, flax, hemp or jute. The parameter relates to any measurable physical characteristic or condition of the crop that is variable. For example, the parameter may comprise yield level, protein content, leaf chlorophyll content, oil content, starch content, fibre content, vitamin, nutrient or mineral content, plant height, leaf area or root depth of the crop.

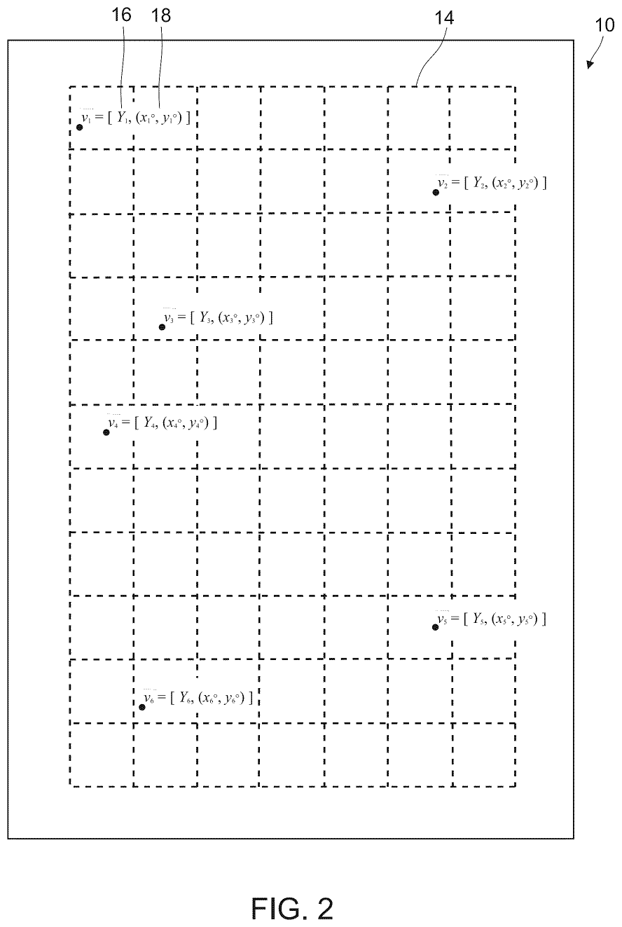

The method comprises a plurality of steps which are executed by a computer 12. Referring to FIG. 2, the steps include generating a point vector layer 14 by a processor of the computer 12. The point vector layer 14 represents a mathematical abstraction of the area of land 10 and comprises a plurality of point vectors that respectively correspond to a plurality of geographical positions on the area of land 10. The geographical positions are points on the area of land 10 that have been ‘sampled’ in advance, as discussed further below. For the sake of simplicity, the point vector layer 14 is shown containing only six point vectors, labelled v₁₋₆, which correspond to a six sampled points on the area of land 10 respectively. In other examples, a higher number of point vectors may be stored in the point vector layer 14 corresponding to a higher number of respective sampled points.

Each point vector comprises a pair of components. The first component is an individual predicted value 16 for the crop parameter. In the example depicted, the relevant crop parameter is crop yield and is measured in suitable units, such as kilograms per hectare (kg/ha). The set of yield values (six in total) that are, accordingly, stored in the point vector layer 14 are labelled Y₁₋₆. The second component in each point vector comprises spatial coordinates 18. The coordinates 18 are assigned to the relevant yield value in the given point vector. A set of six coordinates are, accordingly, stored in the point vector layer 14 which are labelled (x₁₋₆°, y₁₋₆°. The coordinates may be measured in degrees latitude and longitude. The set of coordinates identify the geographical positions of the respective sampled points.

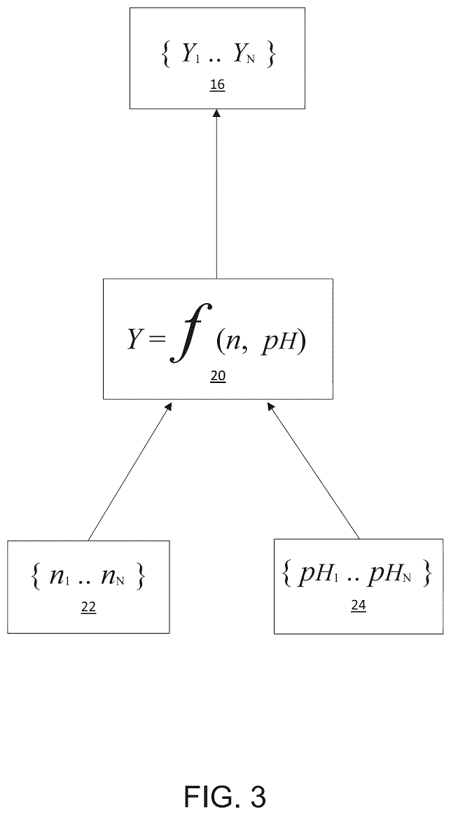

Referring to FIG. 3, each predicted yield value 16 in the point vector layer 14 is generated by the computer 12 using a mixed-effects predictive model 20. The model 20 quantifies an extent to which the variable crop parameter, which in the present case is yield, is affected by both fixed effects 22 and random effects 24. The fixed effects 22 comprise quantities of an agricultural product that are to be applied to the area of land 10 at the sampled points to facilitate crop growth at those points. In the example provided, the relevant agricultural product is a fertiliser that contains nitrogen (N). The quantities of the fertiliser are labelled n_{1-N}. In other examples, the agricultural product may comprise other substances such as herbicide, fungicide, insecticide, seed, traits or an agricultural biological.

The mixed effects 24 used by the model 20 comprise at least one environmental condition of the area of land at the sampled points. The environmental condition includes any physical characteristic or variable relating to the crop's environment that influences the crop's growth, health and/or yield potential on the area of land 10. In embodiments, the environmental condition may relate to the soil in which the crop is to be grown. For example, the environmental condition may comprise soil moisture level, texture, rock quantity, pH or salinity level. In other embodiments, the environmental condition may relate to climatic conditions of the area of land 10, such as average air temperature, precipitation levels, solar radiation levels, average wind speed or average air humidity levels. In other examples, the environmental condition may include pest incidence levels for the area of land 10. In the example depicted, the relevant environmental condition is the pH level of the soil at the sampled points, and is labelled pH_{1-N}.

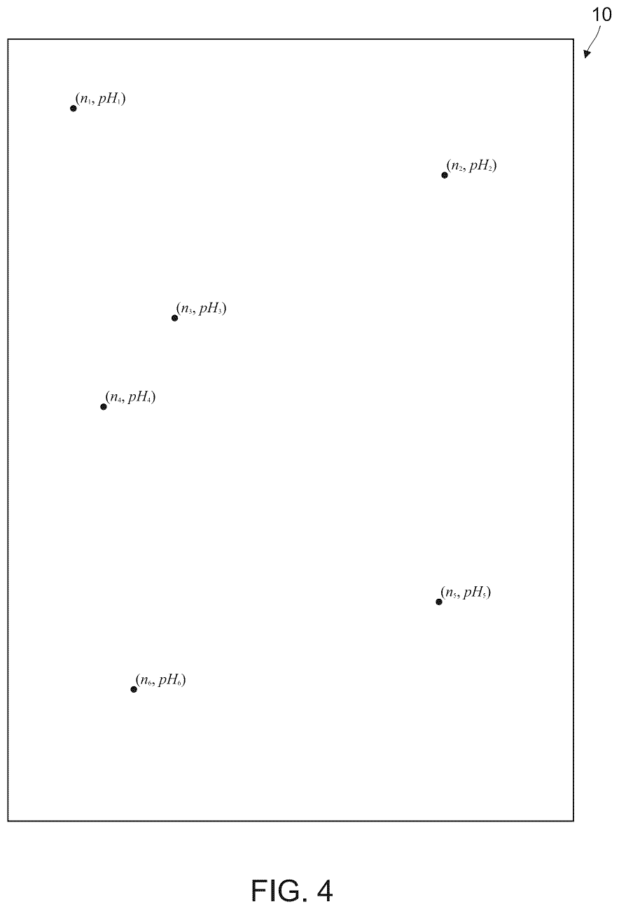

FIG. 4 depicts six nitrogen fertiliser quantities (labelled n₁₋₆) and six soil pH levels (labelled pH₁₋₆) distributed over the area of land 10 at the six respective sampled points. These parameters are supplied as inputs to the predictive model 20. Based on these inputs, the predictive model 20 outputs the six predicted yield values Y₁₋₆ which are stored in the relevant point vectors in the point vector layer 14. The model 20 essentially predicts how the fertiliser quantities and soil pH levels will affect the yield of the crop at each of the sampled points. The data that is used to generate the model 20 is created using a field trial of the fertiliser product that is carried out on the area of land 10 in advance. The field trial methods that are used are more particularly described below.

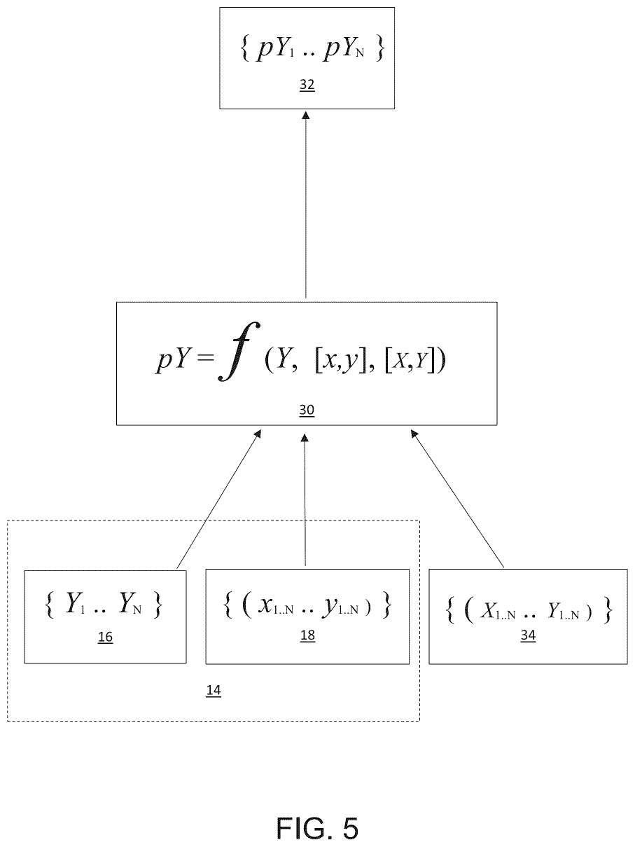

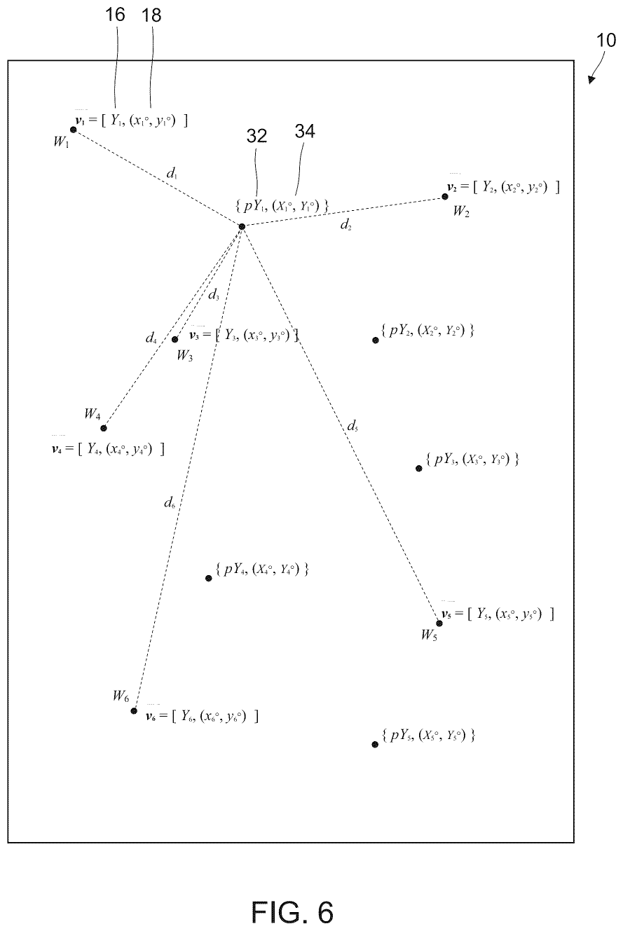

Referring to FIGS. 5 and 6, once the point vector layer 14 is generated, the computer 12 executes an inverse distance weighted interpolation algorithm 30. The algorithm 30 calculates a set of second predicted values 32 for the crop yield which are derived from the set of first predicted crop yield values 16. The second set 32 supplements the first set 16 and corresponds to a set of unsampled points on the area of land 10. The unsampled points are geographically located at positions interposed between the sampled points. For the sake of simplicity, a total of five second predicted values 32 are depicted in FIG. 6, labelled pY_{1 . . . 5}, which correspond to five respective unsampled points on the area of land 10. A significantly higher number of second predicted values 32 may be calculated by the algorithm 30 in other examples.

To calculate the second predicted values 32, the algorithm 30 uses a second set of spatial coordinates 34 in addition to the first set of coordinates 18 in the point vector layer 14. The second coordinates 34 correspond to the geographical positions of the unsampled points and, like the first set 18, may be recorded in degrees latitude and longitude. The second coordinates 34 are assigned to the relevant second predicted yield values 32 and are labelled (X₁₋₅, Y₁₋₅) in FIG. 6.

For each individual second yield value 32 that is to be calculated by the algorithm 30, each individual first yield value 16 has a weighted influence on the value of the second value 32 that is calculated. This weighted influence diminishes in magnitude with increasing spatial distance between the two spatial coordinates 18, 34 that are assigned to the two relevant individual predicted values 16, 32.

By way of example, referring to the individual second yield value 32 that is labelled pY₁ in FIG. 6, it can be seen that each of the six point vectors v_{1 . . . 6} surround pY₁. Each of the first yield values 16 Y_{1 . . . 6} that are stored in these point vectors v_{1 . . . 6} is used to calculate pY₁. The distances between the coordinates 34 that are assigned to pY₁—namely (X₁, Y₁)—and the coordinates 18 that are assigned to v_{1 . . . 6}—namely (x₁₋₆, y₁₋₆)—are labelled d_{1 . . . 6}. The greater the distance d is, the less the influence that the relevant first yield value 16 Y has on the calculated value of pY₁. Conversely, the less the distance d is, the greater the influence that the relevant first yield value 16 Y has on the calculated value of pY₁. Preferably, the algorithm 30 calculates the euclidean distance between the relevant coordinates 18, 34 for the value of d.

The interpolation algorithm may include a normalisation method which ensures that the weighted influence of each first yield value 16 that is used to calculate the individual second yield value 32 is unbiased. In the example depicted, the normalisation method operates by initially calculating a weight, W, for each point vector v_{1 . . . 6} and assigning each W to the relevant point vector. This results in a set of weights that are assigned to the point vectors in the point vector layer 14. These weights are labelled W_{1 . . . 6} in FIG. 6. The value of each weight W is inversely proportional to the relevant spatial distance d. More particularly, each weight value is inversely proportional to a fixed power, p, of the spatial distance, where p≥1. The general relationship between W and dis, therefore, given by the following equation, where i is the relevant point vector:

$${W}_{i} = \frac{1}{{d}_{i}^{p}}$$

The value of the exponent p determines how rapidly the weight decreases with increasing distance d. In one example, the value of p may be 2 such that there is an inverse square relationship between W and d. Accordingly, in such cases there will be a quadratic decay in influence as the distance increases; and the influence will, therefore, decrease at a faster rate as the distance increases.

Once the set of weights have been calculated, the valve of pY₁ for the individual second yield value 32 is calculated using the following equation, where n is the number of sampled points (n=6 in the example depicted):

$$pY = \frac{{\sum }_{i = 1}^{n} {W}_{i} {Y}_{i}}{{\sum }_{i = 1}^{n} {W}_{i}}$$

As can be seen by the above equation, each individual first yield value Yᵢ is multiplied by the relevant weight Wᵢ to obtain a set of scaled first yield values, which are summed together to form the numerator of the equation. The numerator is then divided by a sum of all the weights W_{1 . . . n} (as per the denominator) to obtain the valve of pY₁.

In the example depicted, each of the second yield values 32 labelled pY₁ s in FIG. 6 is calculated using this normalisation method. This results in a second set of yield values 32 being generated which correspond to the unsampled points. In combination with the first set of first yield values 16, labelled Y_{1 . . . 5}, the two sets of predicted values 16, 32 provide quantitative indications of how the yield of the crop will be affected when the fertiliser is applied to the area of land 10 in accordance with the quantities n₁₋₆.

In FIG. 6, only five second yield values 32 are depicted for ease of illustration. However, in practice a significantly higher number of second yield values 32 may be calculated by the weighted interpolation algorithm 30 for a higher number of unsampled locations on the area of land 10. Increasing the number of second yield values 32 enables yield prediction to be performed at a higher resolution.

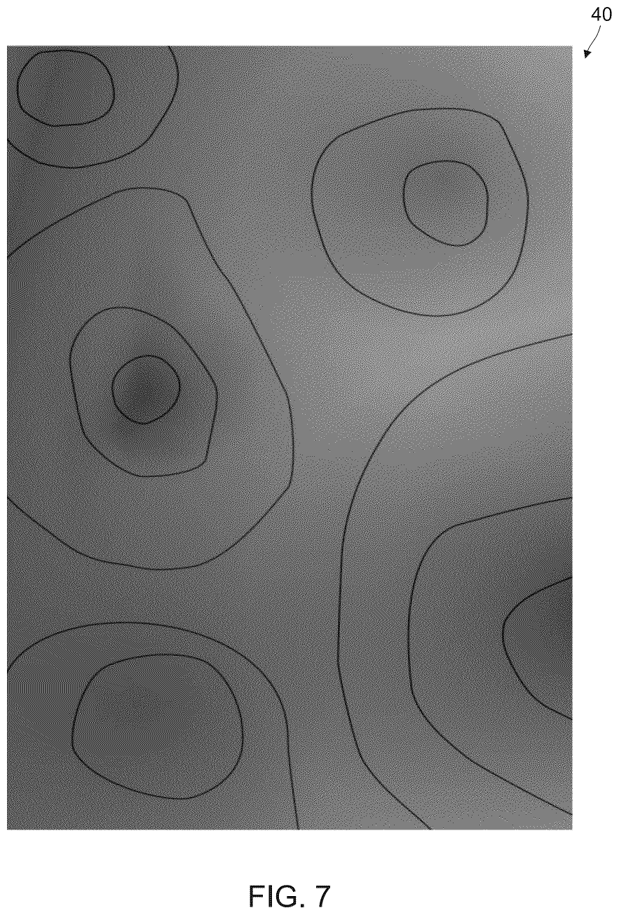

FIG. 7 relates to an example whereby a high number of second yield values 32 are calculated by the algorithm 30 to achieve high-resolution yield prediction. The Figure depicts a gradient map 40 of the area of land 10 that is displayed on a display device connected to the computer 12. The gradient map 40 graphically depicts the spatial variability and distribution of the predicted yield values 16, 32 across the area of land 10. The area of land 10 is displayed on the map 40 by a set of pixels of the display device, wherein each pixel corresponds to a sampled or unsampled point on the area of land 10. Accordingly, each pixel corresponds to one of the predicted yield values 16, 32. The shading and/or colour that is used to fill each pixel is governed by the predicted yield value that is calculated for the relevant sampled/unsampled point; for example, the higher the predicted yield is, the darker the pixel is. By calculating and displaying a predicted yield for each pixel, the gradient map 40 depicts the spatial variability of the predicted yields across the area of land 10 in a continuous visual manner.

As discussed above, the mixed-effects model 20 enables a predicted value of a variable crop parameter to be calculated for any location on the area of land 10 based on quantities of an agricultural product that will be applied at the location and environmental conditions at the location. In the depicted example, the relevant crop parameter is yield, the relevant agricultural product is a nitrogen-based fertiliser and the relevant environmental conditions comprise soil pH. The data that is used to generate the mixed-effects model 20 is created in advance by carrying out a field trial of the agricultural product on the area of land 10. The data is, therefore, created before the method for calculating the predicted values 16, 32 can be executed. After the data has been created using the field trial, the computer 12 generates an instance of the model 20 using the data and stores the model 20 on a memory device of the computer 12. With the model loaded into memory, the method can be executed by the computer 12 any number of iterations. In each iteration, different sets of agricultural product quantity data and environmental condition data may be input into the model 20 corresponding to different sampled locations on the area of land 10.

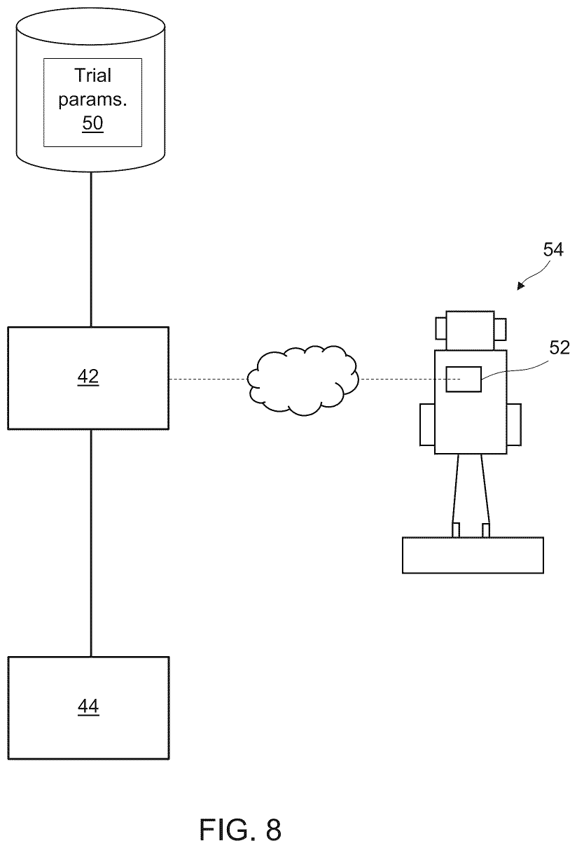

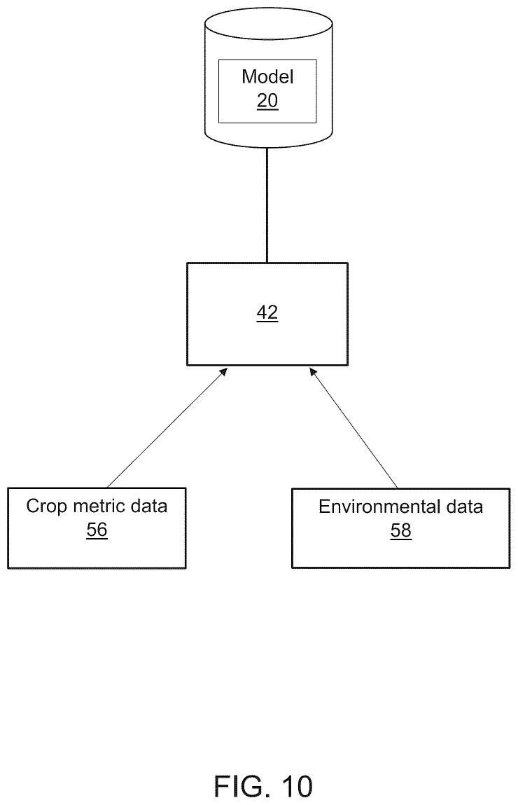

Referring to FIGS. 8-11, the field trial of the agricultural product may be carried out in advance using a computer system 42, which may be computer system 12 or a separate computer system. In the example depicted, computer system 42 is a dedicated server that has been specifically provisioned for agricultural field trials. The model 20 is generated by a method executed by the server 42, which may comprise the steps of: (a) receiving, at the server 42 from a remote device 44, data defining one or more paths or geographical areas 46 extending across the area of land 10 on which the trial of the product is to be performed for the crop; (b) determining, by the server 42, a plurality of test regions 48 that are located on the one or more paths or geographical areas 46; (c) determining, by the server 42, a set of trial parameters 50 for the trial, wherein the trial parameters 50 include application rates or quantities of the product to be applied to each of the test regions 48 respectively; (d) transmitting the trial parameters 50 to a control system 52 of an agricultural machine 54, wherein the trial parameters 50 cause the control system 52 to control the machine 54 to apply the product to the test regions 48 in accordance with the application rates or quantities, as defined by the trial parameters 50, when the machine 54 moves over the test regions 48; (e) receiving, at the server 42 from a remote device 44, crop metric data 56 defining one or more measured characteristics of the crop as grown on each of the test regions 48; (f) receiving, at the server 42 from a remote device 44, environmental data 58 defining environmental conditions at one or more of the test regions 48 on which the crop is grown; (g) determining, by the server 42, the statistical model 20 based on the trial parameters 50, crop metric data 56 and environmental data 58, wherein the statistical model 20 estimates a relationship between the application rates or quantities and the measured characteristics, and wherein the statistical model quantifies an extent to which the relationship is affected by the environmental conditions defined by the environmental data 58.

More particularly, in the example depicted the agricultural product that is being trialled on the area of land 10 is fertiliser containing nitrogen (N). The paths or geographical areas 46 comprise a set of AB-lines that extend across the area of land 10. The crop metric data 56 comprises yield data for the crop. The statistical model 20 generated by the server 42 estimates the relationship between the application rate of the fertiliser that is applied to each test region 48 and the resulting yield of the crop that is grown in each test region 48 respectively. The application rate is the independent or predictor variable in the model 20 and the yield is the dependent or response variable in the model 20. The model 20 estimates the fixed effects that the application rate has on this relationship. That is to say, the model 20 assumes that there is a substantially fixed or constant relationship between the application rate and the resulting crop yield across all test regions 48. The model 20 also estimates the random effects that the environmental conditions have on this relationship. That is to say, the model 20 assumes that there is a variable relationship between the environmental conditions and the resulting crop yield across the test regions 48. In the example depicted, the environmental conditions used by the model 20 comprise soil type information for each of the test regions 48, which is encoded in the environmental data 58 received by the server 42. The model 20 may be a linear or nonlinear mixed-effects statistical model. The depicted example is based on a linear mixed-effects model. The server 42 generates the model 20 using any known technique for producing linear mixed-effects statistical models.

For the sake of simplicity, a total of fifteen test regions 48 are used for the trial that is performed on the example area of land 10. In other examples, a higher or lower number of test regions 48 may be used on the area of land 10, provided that at least one test region 48 is located across the area of land 10 in practice. Furthermore, the test regions 48 may be distributed over the area of land 10 at a spatial density of between (a) 1 test region per 2 hectares of the area of land 10, and (b) 1 test region per 100 hectares of the area of land 10. Preferably, the spatial density will be at least 1 test region per 10 hectares of the area of land 10. The test regions 48 will typically be placed at random positions across the area of land 10 by the server 42. In other examples, the server 42 may receive custom locations for one or more of the test regions 48 from a remote device 44 that is remotely connected to the server 42. For example, the server 42 may receive a set of custom locations over the internet from a personal computer or mobile device operated by the grower who manages the area of land 10. The server 42 may place one or more of the test regions 48 at the custom locations accordingly. By providing the custom locations, the grower can place test regions 48 in areas of the area of land 10 that the grower suspects may have underlying conditions that positively or negatively affect crop yield based on harvest information obtained for previous growing seasons.

The locations of the test regions 48 may coincide with the sampled positions that are depicted in FIG. 1, but this is not mandatory. The model 20 that is generated is of general application for the area of land 10. The model 20 can, therefore, be used to make crop parameter predictions for any location on the area of land 10 in respect of which data is available relating product application quantities/rates and environmental conditions.

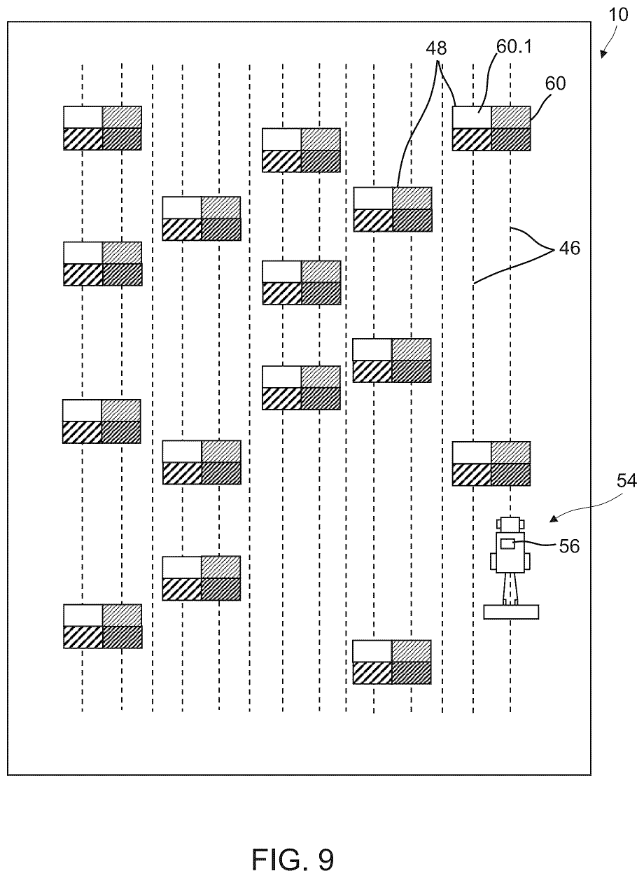

As illustrated in FIG. 9, the server 42 is further configured to subdivide each test region 48 into a plurality of plots 60. Each plot 60 intersects with one of the A-B lines 46. Each test region 48 comprises four of the plots 60 that are arranged in a grid formation. Each plot 60 is substantially rectangular and may be between 10 and 100 metres in width and between 10 and 100 metres in length. In examples where the trial is to be performed at a high resolution, the surface area of each plot 60 may be a maximum of 10,000 square metres. For each test region 48, the trial parameters 50 determined by the server 42 prescribe a different (unique) fertiliser application rate for each of the four plots 60 in the test region 48. Preferably, the four plots 60 in each test region 48 comprise a single control plot 60.1 and three test plots. The trial parameters 50 prescribe a nil application rate for the control plot 60.1 and a non-nil application rate for each test plot.

The rates for the plots 60 for each test region 48 will be determined by the server 42 either randomly, in accordance with a rate selection algorithm executed by the server 42, or in accordance with parameters provided to the server 42 by an administrative user of the system. The server 42 may include functionality that enables the grower to submit a level of risk to the server 42 that the grower is willing to assume for the trial. When a level of risk is submitted, the server 42 will determine the trial parameters, including the rates for the plots 60, in accordance with the level of risk. For example, the server 42 may prescribe higher rates of fertiliser for the trial if the grower is willing to assume a higher level of risk.

In the embodiment depicted, the agricultural machine 54 comprises a tractor towing a pull-type crop sprayer. The control system 52 controls the tractor 54 automatically and causes the tractor 54 to pull the crop sprayer along each of the A-B lines 46 in sequence. When the crop sprayer encounters one of the test regions 48, the control system 52 causes the crop sprayer to deposit the fertiliser product onto the plots 60 of the test region 48 in accordance with the relevant rates defined by the trial parameters 50 for the plots 60. The control system 42 may be connected to a user interface provided on the tractor 54 that allows the driver of the tractor 54 to interact with the control system 52 during this process. For example, the user interface may provide a button, tool or similar user interface control that enables the driver to stop or suspend the application of the fertiliser at any point in time.

It will be appreciated that the crop sprayer towed by the tractor 54 may not be capable of instantaneously depositing the fertiliser at the application rates defined by the trial parameters 50 as the crop sprayer advances onto the respective plots 60. For example, it may take the crop sprayer a period of about two seconds to accelerate or decelerate the application rate from its current value to the rate required for a plot 60. This includes where the crop sprayer is (a) transitioning from a region of the area of land 10 that is outside a test region 48 to a plot 60 within a test region 48 (in which case the application rate must increase from nil to a required rate) and (b) transitioning across the boundary between two plots 60 inside a given test region 48 (in which case the application rate must change from rate A to rate B, where A≠B).

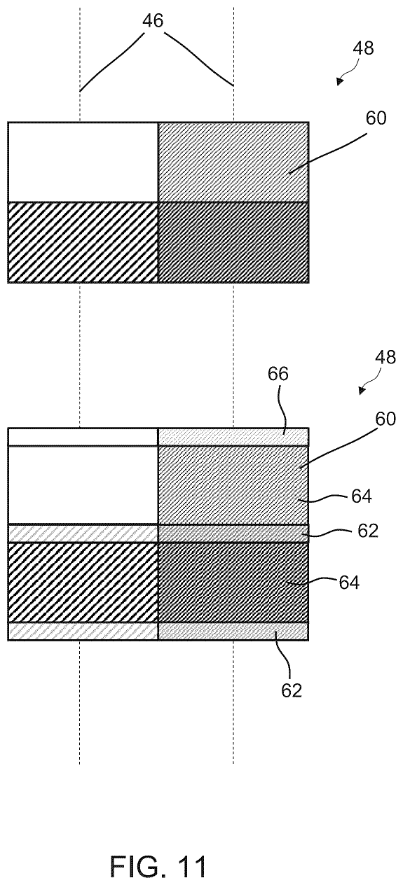

Referring to FIG. 11, in such examples, the trial parameters 50 will define a lead-in zone 62 that is located at an outermost edge of each plot 60 facing the approaching crop sprayer. The trial parameters 50 will also define a central zone 64 adjacent to the lead-in zone 62. The trial parameters 50 will also define a lead-out zone 66 that is located at an outermost edge of each plot 60 facing away from the approaching crop sprayer. The trial parameters 50 cause the crop sprayer to (a) increase the application rate of the fertiliser as the crop sprayer travels through the lead-in zone 62, (b) keep the application rate substantially constant as the crop sprayer travels through the central zone 64, and (c) decrease the application rate as the crop sprayer travels through the lead-out zone 66. The server 42 is, therefore, able to determine that the fertiliser has been applied to each plot 60 at a substantially constant rate at least while the crop sprayer has been travelling across the central zone 64 of the plot 60.

The fertiliser will typically be applied to the test regions 48 during the fertilisation stage of the crop cycle for the given area of land 10. Once applied, the crop is left to grow until the harvest stage of the cycle is reached. The yield of the crop will then be measured. In examples where a crop parameter other than yield is measured, multispectral image data of the area of land 10 may be obtained that can be used to determine the relevant characteristics of the crop in the plots 40 in each test region 48. These data may comprise vegetation index data, such as normalised difference vegetation index (NDVI) data, collected by satellite, drone or aeroplane. The image data will typically be remotely transmitted to the server 42 for processing to calculate the relevant crop parameter values.

In the example depicted, completing the field trial results in a set of yield measurements 56 being acquired for the test regions 48. The mixed-effects statistical model 20 can be constructed using the yield measurements 56 and the environmental data 58 that was collected for the test regions 48. As discussed above, the statistical model 20 can subsequently be used by the method for calculating the set of predicted values 16, 32.

In addition to producing gradient maps 40 as illustrated in FIG. 7, the predicted values 16, 32 can be used for other useful purposes. For example, in embodiments where the predicted values 16, 32 define predicted crop yield levels, these predicted yields 16, 32 can be used to generate prescription maps for the relevant agricultural product for use by growers on the area of land 10. These prescription maps will define quantities and/or application rates of the agricultural product which, when applied to the area of land 10, assist in achieving the predicted yields 16, 32. For example, if the agricultural product is a nitrogen-based fertiliser, then the predicted crop yields 16, 32 can be used to generate a nitrogen prescription map for the area of land 10. The prescription map data may be transmitted from the computer 12 to a control system 52 of an agricultural machine 54. The control system 52 may then autonomously control the machine 54 and apply the nitrogen-based fertiliser onto the area of land 10 in accordance with the quantities and/or rates defined by the prescription map.

Referring to FIG. 4, the six fertiliser quantities that are labelled n₁₋₆ correspond to the six sampled points on the area of land 10. It will, therefore, be appreciated that these six quantities can be used directly in a prescription map created for the area of land 10 that defines fertiliser quantities for the sampled points. For the unsampled points on the area of land 10, a further set of quantities must be calculated for these points and inserted into the prescription map. The further quantities can be calculated using various different methods. In one method, the further set of quantities is calculated by interpolating the quantities n₁₋₆ corresponding to the sampled points, taking into account the spatial variances between the sampled and unsampled points. A linear or non-linear interpolation method may be used in such examples.

A more complex method uses a model inversion of the predictive model 20. The model inversion is, essentially, a variant of the predictive model 20 that operates in reverse. Whereas the model 20 receives fertiliser quantities nix and PH levels pH_{1-N} as input parameters and calculates a set of predicted yield levels Y_{1-N} as an output, the model inversion receives predicted yield levels Y_{1-N} and PH levels pH_{1-N} as input parameters and calculates a set of fertiliser quantities as an output. In the example depicted, the measured (i.e., known) pH levels at the sampled points, pH_{1-N} can be used to calculate estimated PH levels at the unsampled points on the area of land 10. These estimated pH levels may be calculated by interpolating the measured pH levels, taking into account the spatial variances between the sampled and unsampled points. A linear or non-linear interpolation method may be used. The estimated PH levels and the second predicted yield levels pY_{1-N} may then be supplied as inputs to the model inversion. Based on these inputs, the model inversion will generate a set of fertiliser quantities for the unsampled points. The fertiliser quantities for the sampled points and for the unsampled points can then be used to create the final nitrogen prescription map.

The operations of each method herein disclosed may be implemented by one or more software modules executed by a controller or computer processor. Each software module may be embodied in a non-transitory computer-readable medium storing computer-executable instructions for performing operations of the method. The controller may comprise a programmable logic controller (PLC), a programmable logic array (PLA) or similar electronic controller device, including multiple electronic controller devices connected together via a network or a similar communication means. As used herein, processor refers to a device capable of executing instructions encoding arithmetic, logical, and/or I/O operations and includes both a physical and a virtual processor. In one aspect, a processor may be a single core processor which is typically capable of executing one instruction at a time (or process a single pipeline of instructions), or a multi-core processor which may simultaneously execute multiple instructions. In another aspect, a processor may be implemented as a single integrated circuit, two or more integrated circuits, or may be a component of a multi-chip module (e.g., in which individual microprocessor dies are included in a single integrated circuit package and share a single socket). A processor may also be referred to as a central processing unit (CPU).

For the purpose of this specification, the word “comprising” means “including but not limited to”, and the word “comprises” has a corresponding meaning. It is to be understood that, if any prior art is referred to herein, such reference does not constitute an admission that the prior art forms a part of the common general knowledge in the art, in Australia or any other country.

The above embodiments have been described by way of example only and modifications are possible within the scope of the claims that follow.

1. A method comprising:
generating, by a computer system, a predictive model for a crop parameter, wherein the predictive model is based on fixed effects representing quantities of an agricultural product and random effects representing environmental conditions measured at sampled points on an area of land;
receiving, at the computer system, data comprising quantities of the agricultural product to be applied to the sampled points and environmental conditions at the sampled points;
generating, by the computer system, a set of first predicted values for the crop parameter at the sampled points using the predictive model and the data received;
generating, by the computer system, a point vector layer that comprises the set of first predicted values, wherein a set of first spatial coordinates that correspond to the sampled points are respectively assigned to the first predicted values in the point vector layer; and
executing, by the computer system, an inverse distance weighted interpolation algorithm, based on the point vector layer, to calculate a set of second predicted values for the crop parameter for unsampled points on the area of land, wherein the interpolation algorithm includes assigning a set of second spatial coordinates that correspond to the unsampled points to the second predicted values respectively, and wherein a weighted influence of each first predicted value on each second predicted value diminishes as the spatial distance between the respective spatial coordinates increases,
such that the first and second sets of predicted values provide a quantitative indication of how the crop parameter is expected to be affected by the agricultural product across the area of land.

2. The method according to claim 1, wherein the interpolation algorithm includes a normalisation method which provides that the weighted influence of each individual first predicted value that is used to calculate each individual second predicted value is unbiased.

3. The method according to claim 2, wherein the normalisation method comprises:
calculating a weight for each individual first predicted value, wherein the weight is inversely proportional to the spatial distance between the respective spatial coordinates that are assigned to the individual first predicted value and the individual second predicted value, to obtain a set of weights;
multiplying each individual first predicted value by each of the weights respectively to obtain a set of scaled first predicted values; and
dividing a sum of the scaled first predicted values by a sum of the weights to obtain the individual second predicted value.

4. The method according to claim 3, wherein each weight is inversely proportional to a fixed power of the spatial distance, wherein the fixed power is greater than one.

5. The method according to claim 4, wherein the fixed power is equal to two.

6. The method according to claim 1, wherein the spatial distance is a euclidean distance between the respective spatial coordinates.

7. The method according to claim 1, wherein the method further comprises generating and displaying a map on a display device connected to the computer system, wherein the map graphically depicts a spatial variability of the first and second predicted values across the area of land.

8. The method according to claim 7, wherein the area of land is displayed on the map by a set of pixels of the display device, and wherein the method further comprises calculating and depicting a predicted value of the crop parameter for each of the pixels such that the pixels display a gradient map depicting the spatial variability in a continuous visual manner.

9. The method according to claim 1, wherein the crop parameter comprises crop yield level.

10. The method according to claim 1, wherein the agricultural product comprises nitrogen.

11. The method according to claim 1, wherein the environmental conditions comprise soil pH.

12. The method according to claim 1, wherein the method further comprises:
calculating, by the computer system, a further set of quantities of the agricultural product, wherein the further set of quantities correspond to the unsampled points respectively and are for growing the crop in accordance with the second predicted values; and
remotely transmitting at least the further set of quantities from the computer system to a control system of an agricultural vehicle to enable the control system to cause the agricultural vehicle to apply the agricultural product to the area of land autonomously in accordance with the further set of quantities.

13. The method according to claim 12, wherein the further set of quantities is calculated by interpolating the quantities of the agricultural product that are to be applied at the sampled points.

14. The method according to claim 12, wherein the method further comprises:
executing, by the computer system, an interpolation algorithm to generate environmental data containing estimates of the environmental conditions of the area of land at the unsampled points, wherein the interpolation algorithm generates the environmental data based on the environmental conditions of the area of land at the sampled points; and
generating, by the computer system, the further set of quantities using a model inversion of the predictive model, wherein the model inversion receives the environmental data and the set of second predicted values as inputs.

15. A system comprising a processor, wherein the processor is configured to:
generate a predictive model for a crop parameter, wherein the predictive model is based on fixed effects representing quantities of an agricultural product and random effects representing environmental conditions measured at sampled points on an area of land;
receive data comprising quantities of the agricultural product to be applied to the sampled points and environmental conditions at the sampled points;
generate a set of first predicted values for the crop parameter at the sampled points using the predictive model and the data received;
generate a point vector layer that comprises the set of first predicted values, wherein a set of first spatial coordinates that correspond to the sampled points are respectively assigned to the first predicted values in the point vector layer; and
execute an inverse distance weighted interpolation algorithm, based on the point vector layer, to calculate a set of second predicted values for the crop parameter for unsampled points on the area of land, wherein the interpolation algorithm includes assigning a set of second spatial coordinates that correspond to the unsampled points to the second predicted values respectively, and wherein a weighted influence of each first predicted value on each second predicted value diminishes as the spatial distance between the respective spatial coordinates increases,
such that the first and second sets of predicted values provide a quantitative indication of how the crop parameter is expected to be affected by the agricultural product across the area of land.

16. A computer-readable non-transitory medium storing executable instructions which, when executed by a computer system, cause the computer system to:
generate a predictive model for a crop parameter, wherein the predictive model is based on fixed effects representing quantities of an agricultural product and random effects representing environmental conditions measured at sampled points on an area of land;
receive data comprising quantities of the agricultural product to be applied to the sampled points and environmental conditions at the sampled points;
generate a set of first predicted values for the crop parameter at the sampled points using the predictive model and the data received;
generate a point vector layer that comprises the set of first predicted values, wherein a set of first spatial coordinates that correspond to the sampled points are respectively assigned to the first predicted values in the point vector layer; and
execute an inverse distance weighted interpolation algorithm, based on the point vector layer, to calculate a set of second predicted values for the crop parameter for unsampled points on the area of land, wherein the interpolation algorithm includes assigning a set of second spatial coordinates that correspond to the unsampled points to the second predicted values respectively, and wherein a weighted influence of each first predicted value on each second predicted value diminishes as the spatial distance between the respective spatial coordinates increases,
such that the first and second sets of predicted values provide a quantitative indication of how the crop parameter is expected to be affected by the agricultural product across the area of land.
